(19) United States
(12) Patent Application Publication
(10) Pub. No.: US 2023/0236264 A1
(43) Pub. Date: Jul. 27, 2023

(54) METHODS, SYSTEMS AND TERMINAL DEVICES FOR ANALYZING CELL STATES BASED ON CELL PARAMETERS

(71) Applicant: SHANGHAI MAKESENS ENERGY STORAGE TECHNOLOGY CO., LTD., Shanghai (CN)

(72) Inventors: Weikun Wu, Shanghai (CN); Peng Ding, Shanghai (CN); Danfei Gu, Shanghai (CN); Pingchao Hao, Shanghai (CN); Pei Song, Shanghai (CN); Xiao Yan, Shanghai (CN); Enhai Zhao, Shanghai (CN); Xiaohua Chen, Shanghai (CN); Guopeng Zhou, Shanghai (CN); Mingchen Jiang, Shanghai (CN); Wei Xiao, Shanghai (CN)

(21) Appl. No.: 18/101,174

(22) Filed: Jan. 25, 2023

(30) Foreign Application Priority Data
Jan. 26, 2022 (CN) 202210093889.7
Jan. 26, 2022 (CN) 202210095425.X

(51) Int. Cl. G01R 31/396; G01R 31/367; G01R 31/3842

(52) U.S. Cl. CPC G01R 31/396; G01R 31/367; G01R 31/3842

(57) ABSTRACT

The invention provides methods, systems and terminal devices for analyzing a state of a battery pack based on cell parameters thereof. The method comprises acquiring cell voltages of each cell and total voltages of the battery pack within a preset time; performing data cleaning on the cell voltages and the total voltages of the battery pack; calculating a voltage standard score of the cells based on the cell voltages after data cleaning, and calculating a voltage standard score of the battery pack based on the total voltages after data cleaning; and performing a time-domain analysis on the voltage standard score of each cell and/or the voltage standard score of the battery pack.

### CROSS-REFERENCE TO RELATED PATENT APPLICATIONS

This application claims priority to and the benefit of Chinese Patent Application Nos. 202210095425.X and 202210093889.7, both filed Jan. 26, 2022, which are incorporated herein in their entireties by reference.

### FIELD OF THE INVENTION

The invention relates generally to the field of data analysis, and more particularly to methods, systems and terminal devices for analyzing cell states based on cell parameters.

### BACKGROUND OF THE INVENTION

At present, a large number of batteries are used in energy storage power stations and new energy vehicles. Different manufacturers, different manufacturing processes, and different operating conditions may inevitably cause inconsistency in battery packs. In actual use, the charge and discharge control of the battery pack is determined by the cells with the worst charge and discharge performance, and the inconsistency may affect the safe operation of the energy storage power stations and new energy vehicles, and even causes safety hazards. In order to ensure the safety of the battery packs in long-term use, it is necessary to continuously monitor and analyze the operating data of the battery packs. It is particularly important to find those cells and battery packs that appear inconsistent in time.

In the prior art, the inconsistency in the battery packs is generally adjusted and improved by means of physical balancing, so the operating state of the battery packs can be returned to a normal state. However, the cost of such physical balancing is relatively high.

In addition, to determine the consistency in the battery pack and/or each single cell thereof, it is necessary to use professional tools to perform high-precision measurements on the battery pack and/or the cells thereof, e.g., to measure the capacity, internal resistance, and charge-discharge curves, under laboratory conditions. Meanwhile, high-frequency data is generally required in order to obtain more accurate results. Although the method may accurately obtain the internal conditions of the battery pack, it is inconvenient to disassemble the cells and send it to the laboratory for testing in the actual application process.

Therefore, a heretofore unaddressed need exists in the art to address the aforementioned deficiencies and inadequacies.

### SUMMARY OF THE INVENTION

In view of the aforementioned deficiencies and inadequacies in the prior art, one of the objectives of this invention is to provide methods, systems and terminal devices for quickly analyzing an internal state of a battery pack in actual working conditions, based on cell parameters of the battery pack, which can effectively improve the safety, efficacy and life of the battery pack.

In one aspect, the invention provides a method for analyzing a state of a battery pack based on voltages thereof. The method includes the steps of acquiring cell voltages of each cell and total voltages of the battery pack within a preset time; performing data cleaning on the cell voltages and the total voltages; calculating a voltage standard score of each cell based on the cell voltages after data cleaning; calculating a voltage standard score of the battery pack based on the total voltages after data cleaning; and performing a time-domain analysis on the voltage standard score of each cell and/or the voltage standard score of the battery pack.

In one embodiment, the step of calculating the voltage standard scores of the cells based on the cell voltages after data cleaning includes the steps of calculating the mean or median value μ_{c} and the standard deviation σ_{c} of the cell voltages after data cleaning within the preset time; and calculating the voltage standard score

$${S}_{i} = \frac{{V}_{i} - {μ}_{c}}{{σ}_{c}}$$

of each cell, where Vᵢ represents the voltage value of the i-th cell in the battery pack.

In one embodiment, the time-domain analysis of the voltage standard scores of the cells comprises the steps of dividing the preset time into time intervals of equal length; and obtaining a variation trend of the voltage standard scores of the battery cells, based on the time intervals.

In one embodiment, the method further includes constructing a scatter diagram based on the voltage standard score at time intervals; and constructing a linear variation trend diagram of the voltage standard score based on the scatter diagram.

In one embodiment, the time-domain analysis of the voltage standard of the battery pack includes the steps dividing the preset time into time intervals of equal length; and obtaining a variation trend of the voltage standard score of the battery pack, based on the time intervals.

In one embodiment, the method also includes the steps of constructing a scatter diagram based on the voltage standard scores at time intervals; and constructing a linear variation trend diagram of the voltage standard scores based on the scatter diagram.

In another aspect, the invention provides a system for analyzing a state of a battery pack based on voltages thereof. The system includes an acquisition module, a cleaning module, a calculation module and an analysis module.

The acquisition module is configured to acquire the cell voltages and the total voltages of the battery pack within the preset time.

The cleaning module is configured to clean the acquired data of the cell voltages and the total voltages.

The calculation module is configured to calculate the voltage standard scores of the cells based on the cell voltages after data cleaning, and calculate the voltage standard scores of the battery pack based on the total voltages after data cleaning.

The analysis module is configured to perform the time-domain analysis on the voltage standard scores of the cells and/or the voltage standard score of the battery pack.

In yet another aspect, the invention provides a terminal device for analyzing a state of a battery pack based on voltages thereof. The terminal device includes at least one processor and a memory. The memory is used to store computer programs. The processor is configured to execute the computer programs stored in the memory, so that the terminal device executes the above-disclosed method for analyzing the state of the battery pack.

In one aspect, the invention relates to a method for analyzing a state of a battery pack based on cell parameters thereof. The method comprises acquiring cell parameters of the battery pack within a preset time, wherein the cell parameters include voltage value and current value of each cell; preprocessing the acquired cell parameters; and calculating one or more combinations of a voltage standard score, voltage speed, voltage acceleration and dq/dv under different working conditions based on the preprocessed cell parameters, and obtaining the cell state under the working conditions.

In one embodiment, said preprocessing the cell parameters comprises cleaning abnormal data in the acquired cell parameters; and classifying the cleaned cell parameters according to the working conditions of charging, discharging, and standing.

In one embodiment, said calculating the voltage standard score under different working conditions based on the preprocessed cell parameters, and obtaining the cell state comprises for a certain working condition, calculating a mean or median value μ_{c} and a standard deviation σ_{c} of the preprocessed voltage values; calculating a voltage standard score

$${S}_{i} = \frac{{V}_{i} - {μ}_{c}}{{σ}_{c}}$$

of each cell, where Vᵢ represents the voltage value of the i-th cell in the battery pack; and calculating a median or average value of the voltage standard score within the preset time, wherein

when |the median or average value of the voltage standard score|<a first threshold value, it is determined that the cell is in a healthy state;

when the first threshold value ≤|the median or average value of the voltage standard score|<a second threshold value, it is determined that inconsistency occurs in the cell;

when the second threshold value ≤|the median or average value of the voltage standard score|<a third threshold value, it is determined that the inconsistency of the battery pack begins getting worsen; and

when the third threshold value ≤|the median or average value of the voltage standard score|, it is determined that it is necessary to intervene in the inconsistency of the cell.

In one embodiment, the method further comprises calculating an average value and a standard deviation of the voltage standard score, and drawing a scatter diagram based on the average value and the standard deviation.

In one embodiment, said calculating the voltage speed under different working conditions based on the preprocessed cell parameters, and obtaining the cell state comprises for a certain working condition, calculating the voltage velocity, dv/dt, that is, the first derivative of the voltage with respect to time; and based on the voltage speed, determining the internal resistance consistency of the cell and whether a micro-short circuit occurs.

In one embodiment, said calculating the voltage acceleration under different working conditions based on the preprocessed cell parameters, and obtaining the battery state comprises for a certain working condition, calculating the voltage acceleration

$$\frac{d ( dv / dt )}{d t} ;$$

and based on the voltage acceleration, determining the consistency of internal resistances of each cell and whether a micro-short circuit occurs.

In one embodiment, said calculating dq/dv under different working conditions based on the preprocessed cell parameters, and obtaining the cell state comprises for a certain working condition, calculating an amount of electricity, q, based on the current value, I, of the cell; calculating dq/dv based on the amount of electricity and the voltage; and based on the dq/dv, determining the consistency of the capacity of the cell and whether the capacity decay occurs.

In another aspect, the invention relates to a system for analyzing a state of a battery pack based on voltages and currents thereof. The system comprises a parameter acquisition module, a preprocessing module and an analysis module. The parameter acquisition module is configured to acquire the cell parameters of the battery pack within a preset time, wherein the cell parameters include voltage value and current value of each cell. The preprocessing module is configured to preprocess the acquired cell parameters. The analysis module is configured to calculate one or more combinations of a voltage standard score, a voltage speed, a voltage acceleration and dq/dv under different working conditions based on the preprocessed cell parameters, and obtain the cell state under the working conditions.

In yet another aspect, the invention relates to a terminal device for analyzing a state of a battery pack based on voltages and currents thereof. The terminal device comprises a processor and a memory.

The memory is used to store computer programs; and the processor is configured to execute the computer program stored in the memory, so that the terminal device executes the method analyzing a state of a battery pack based on voltages and currents thereof disclosed above.

In view of the foregoing, the methods, systems and terminal devices for analyzing cells states of the battery pack based on the cell parameters including voltages and/or currents thereof have the following advantageous effects.

(1) The internal state of the battery pack can be determined under different working conditions in real time based on the cell parameters, which is convenient for practical use and has a high accuracy rate.

(2) By fitting the linear variation trend, one can visually view the changes inside the battery pack; and by increasing the thresholds, not only can it predict the life of the battery pack and cells, but it can also give an early warning to the system before the BMS alarms.

(3) Cells with inconsistent and poor performance in the battery pack can be quickly identified and determined, which enables to issue timely warns for some cells that have deteriorated or are deteriorating, thereby effectively improving the safety and economic benefits of the batteries. In addition, it may provide a basis for replacing the battery pack and increasing the capacity of the battery pack.

(4) It can accurately determine the micro-short circuit phenomenon of the battery and ensure the safe and stable operation of the battery pack.

### BRIEF DESCRIPTION OF THE DRAWINGS

FIG. 1 shows schematically a flowchart of a method for analyzing a state of a battery pack based on voltages thereof according to one embodiment of the invention.

FIG. 2 shows a box diagram of the voltage standard scores according to one embodiment of the invention.

FIG. 3 shows a linear variation fitting curve of the voltage standard scores according to one embodiment of the invention.

FIG. 4 shows schematically a structural diagram of a system for analyzing a state of a battery pack based on voltages thereof according to one embodiment of the invention.

FIG. 5 is schematically a structural diagram of a terminal device for analyzing a state of a battery pack based on voltages thereof according to one embodiment of the invention.

FIG. 6A shows schematically a flowchart of a method for analyzing a state of a battery pack based on voltages and currents thereof according to one embodiment of the invention.

FIG. 6B shows schematically a flowchart of a method for analyzing a state of a battery pack based on voltages and currents thereof according to another embodiment of the invention.

FIG. 7 shows a box diagram of the voltage standard scores according to one embodiment of the invention.

FIG. 8 shows a scatter diagram of the voltage standard scores according to one embodiment of the invention.

FIG. 9 shows a density distribution histogram of the voltage standard scores according to one embodiment of the invention.

FIG. 10 shows schematically a structural diagram of a system for analyzing a state of a battery pack based on cell parameters thereof according to one embodiment of the invention.

FIG. 11 is schematically a structural diagram of a terminal device for analyzing a state of a battery pack based on cell parameters thereof according to one embodiment of the invention.

### DETAILED DESCRIPTION OF THE INVENTION

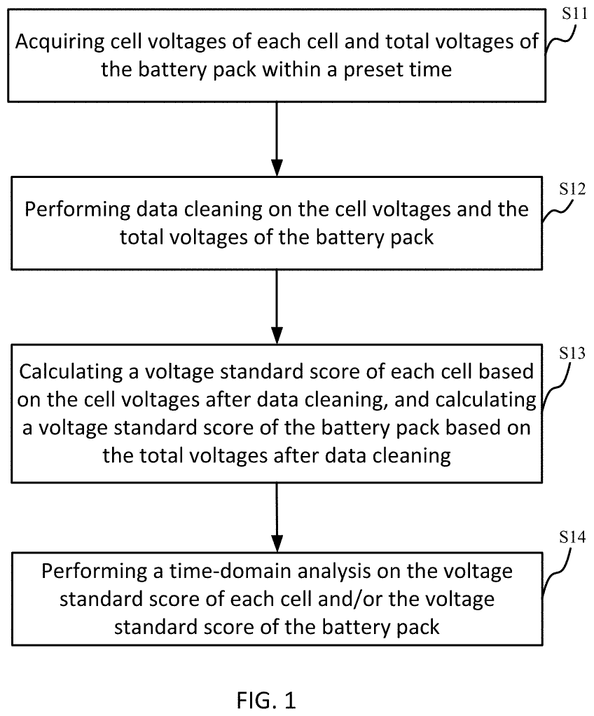

Embodiments of the invention are described below through specific examples in conjunction with the accompanying drawings in FIGS. 1-11, and those skilled in the art can easily understand other advantages and effects of the invention from the content disclosed in this specification. The invention can also be implemented or applied through other different specific implementations, and various modifications or changes can be made to the details in this specification based on different viewpoints and applications without departing from the spirit of the invention. It should be noted that, in the case of no conflict, the following embodiments and features in the embodiments can be combined with each other.

It should be noted that the drawings provided in the following embodiments are merely illustrative in nature and serve to explain the principles of the invention, and are in no way intended to limit the invention, its application, or uses. Only the components related to the invention are shown in the drawings rather than the number, shape and size of the components in actual implementations. Dimensional drawing, the type, quantity and proportion of each component can be changed arbitrarily in its actual implementations. More complicate component layouts may also become apparent in view of the drawings, the specification, and the following claims.

In accordance with the purposes of the invention, as embodied and broadly described herein, this invention, in certain aspects, relates to methods, systems and terminal devices for analyzing cell states of battery packs/modules based on cell parameters thereof. The cell parameters can be cell voltages and total voltages, or cell voltages and cell currents.

It should be noted that as used herein, the terms, “battery module” and “battery pack” are exchangeable and refer to a battery assembly including a plurality of battery cells electrically coupled to each other in series and in parallel; and the terms, “battery cell” and “cell” are exchangeable and refer to a single electrochemical cell/unit that converts the chemical energy into electrical energy.

### Example 1

In this exemplary EXAMPLE 1, a method, a system and a terminal device are developed to analyze internal states of a battery pack, which are based on merely the internal voltage information of the battery pack, and with no need of professional equipment and disassembling the battery pack.

As shown in FIG. 1, in one embodiment, the voltage-based battery pack state analysis method utilizes the cell parameters including cell voltages and total voltages to determine the cell states of the battery pack. The method comprises the following steps.

At step S11, the cell voltage of each cell in the battery pack and the total voltages of the battery pack are acquired within a preset time.

Specifically, the preset time can be 24 hours, two days, one week, etc. Generally, the more data are collected in the preset time, the better, and thus the preset time can be set longer, e.g., three months, half a year, one year, etc. If the preset time is longer enough, it can be divided into time intervals by day. If the present time is not too long, it can be divided by hours, e.g., 1 hour, 4 hours, 6 hours, etc. During the preset time, the cell voltage of each cell in the battery pack and the total voltage of the battery pack are acquired/detected at each divided time interval.

At step S12, data cleaning is performed on the acquired cell voltages and the acquired total voltages of the battery pack.

Specifically, data cleaning is the process of re-examining and verifying data, with the purpose of deleting duplicate information, correcting existing errors, and providing data consistency. Therefore, in order to ensure the validity of the acquired cell voltages and total voltages, a data cleaning operation is performed to eliminate abnormal data.

At step S13, the voltage standard score of each cell is calculated based on the cell voltage after data cleaning, and the voltage standard score of the battery pack is calculated based on the total voltage after data cleaning, respectively.

Specifically, said calculating the voltage standard score of each cell based on the cell voltage after data cleaning includes the steps of:

calculating the mean or median value μ_{c} and the standard deviation σ_{c} of the cell voltage after data cleaning within the preset time; and

calculating the voltage standard score

$${S}_{i} = \frac{{V}_{i} - {μ}_{c}}{{σ}_{c}}$$

of each cell, where Vᵢ represents the voltage value of the i-th cell in the battery pack.

In one embodiment, after the voltage standard score of each cell is calculated, the median or average value of the voltage standard score of the cell within the preset time is calculated. When |the median or average value of the voltage standard score|<a first threshold value, it is determined that the cell is in a healthy state; when the first threshold value ≤|the median or average value of the voltage standard score|<a second threshold value, it is determined that inconsistency occurs in the battery cell; when the second threshold value ≤|the median or average value of the voltage standard score|<a third threshold value, it is determined that the inconsistency of the cell begins getting worsen; when the third threshold value ≤|the median or average value of the voltage standard score|, it is determined that it is necessary to intervene in the inconsistency of the battery cell. In certain embodiments, the first threshold value, the second threshold value and the third threshold value may be set according to actual application scenarios. Ideally, the voltage standard score of each cell in the battery pack should be 0. However, due to differences in manufacturing processes and operating conditions, the voltage standard score of each single cell may be different in actual situations, so the battery cell with poor performance inside the battery pack can be screened based on the voltage standard score of the battery cell. It should be noted that used herein, the terms, “|A|” represents an absolute value of A; “A<B” represents that A is less than B; and “A≤B” represents that A is equal to or less than B.

In one embodiment, said calculating the voltage standard score of the battery pack based on the total voltage after data cleaning includes calculating the mean or median value μ and the standard deviation σ of the total voltage after data cleaning within the preset time.

In one embodiment, after the voltage standard score of the battery pack is calculated, the median or average value of the voltage standard score within the preset time is calculated. When |the median or average value of the voltage standard score|<a first threshold value, it is determined that the battery pack is in a healthy state; when the first threshold value ≤|the median or average value of the voltage standard score|<a second threshold value, it is determined that inconsistency occurs in the battery pack; when the second threshold value ≤|the median or average value of the voltage standard score|<a third threshold value, it is determined that the inconsistency of the battery pack begins getting worsen; and when the third threshold value ≤|the median or average value of the voltage standard score|, it is determined that it is necessary to intervene in the inconsistency of the battery pack. In certain embodiments, the first threshold value, the second threshold value and the third threshold value may be set according to actual application scenarios. Ideally, the voltage standard score of the battery pack should be 0. However, due to differences in manufacturing processes and operating conditions, the voltage standard score of the battery pack may be different in actual situations, so the battery pack with poor performance can be screened based on the voltage standard score of the battery pack.

At step S14, a time-domain analysis is performed on the voltage standard score of the cells and/or the voltage standard score of the battery pack.

In one embodiment, the time-domain analysis is performed on the voltage standard scores only when the third threshold value ≤|the median or average value of the voltage standard score|is satisfied, or is performed on all the obtained voltage standard scores.

In one embodiment, the time-domain analysis of the voltage standard score of the cells comprises dividing the preset time into time intervals of equal length; and obtaining the variation trend of the voltage standard score of the cells based on the time intervals.

Specifically, according to the length of the preset time, it is divided into intervals of equal length, such as the time interval is one day, 12 hours, 6 hours, 4 hours, or 1 hour, etc. It is necessary to select a suitable time interval according to the actual situation.

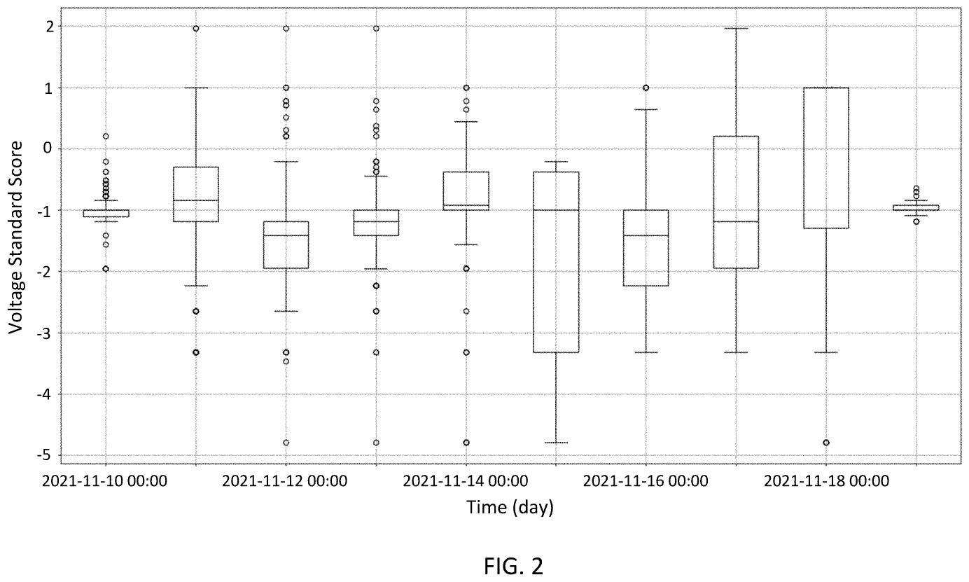

With the time interval as a time unit, the variation trend of the battery cell is analyzed according to the voltage standard score of the battery cell. For example, if the variation trend of the voltage standard score of the battery cell is stable, it indicates that the battery cell is normal; if the variation trend of the voltage standard score of the battery cell is obvious, it indicates that the battery cell is abnormal. In one embodiment as shown in FIG. 2, a box diagram is drawn based on the voltage standard score of the battery cell, where the variation trend of the voltage standard score can be clearly known.

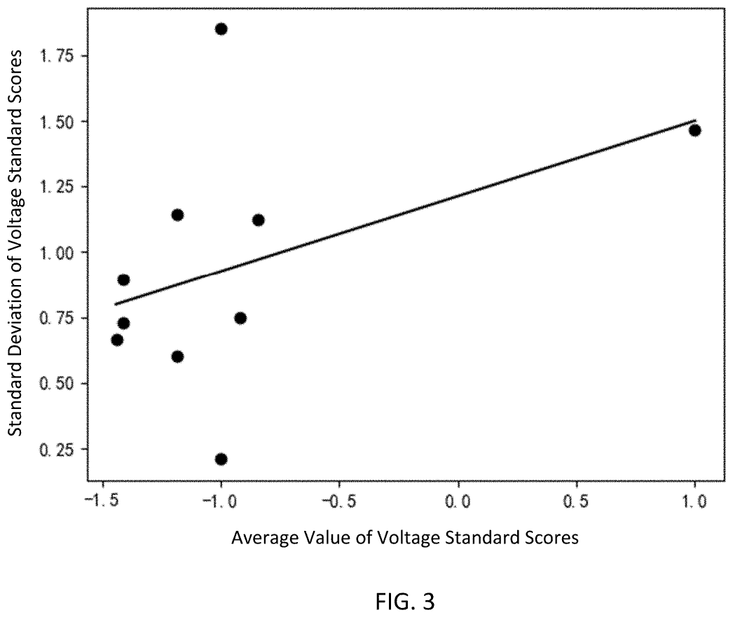

In one embodiment, a scatter diagram is constructed based on the voltage standard score of the cells at time interval points; and a linear variation trend diagram of the voltage standard scores is constructed based on the scatter diagram. Specifically, for the voltage standard score at each time intervals, the scatter diagram is drawn, and then the linear variation trend curve is fitted based on the scatter diagram, as shown in FIG. 3, so as to obtain the variation trend of the voltage standard score of the battery cell. This trend can represent a variation trend of the internal state of the battery. In one embodiment, the time-domain analysis of the voltage standard of the battery pack includes dividing said preset time into time intervals of equal length, and obtaining the variation trend of the voltage standard score of the battery pack based on the time intervals.

Specifically, according to the length of the preset time, it is divided into intervals of equal length, such as the time interval is one day, 12 hours, 6 hours, 4 hours, or 1 hour, etc. It is necessary to select a suitable time interval according to the actual situation.

With the time interval as a time unit, the variation trend of the battery pack is analyzed according to the voltage standard score of the battery pack. For example, if the variation trend of the voltage standard score of the battery pack is stable, it indicates that the battery pack is normal; if the variation trend of the voltage standard score of the battery pack is obvious, it indicates that there is an abnormality inside the battery pack. In one embodiment, a box diagram is drawn based on the voltage standard score of the battery pack, so that the variation trend of the voltage standard score can be clearly known.

In one embodiment, a scatter diagram is constructed based on the voltage standard score of the battery pack at time intervals; and a linear variation trend diagram of the voltage standard score is constructed based on the scatter diagram. Specifically, for the voltage standard score at each time interval, the scatter diagram is drawn, and then the linear variation trend curve is fitted based on the scatter diagram, so as to obtain the variation trend of the voltage standard score of the battery pack. This trend can be characterized a variation trend of the internal state of the battery pack.

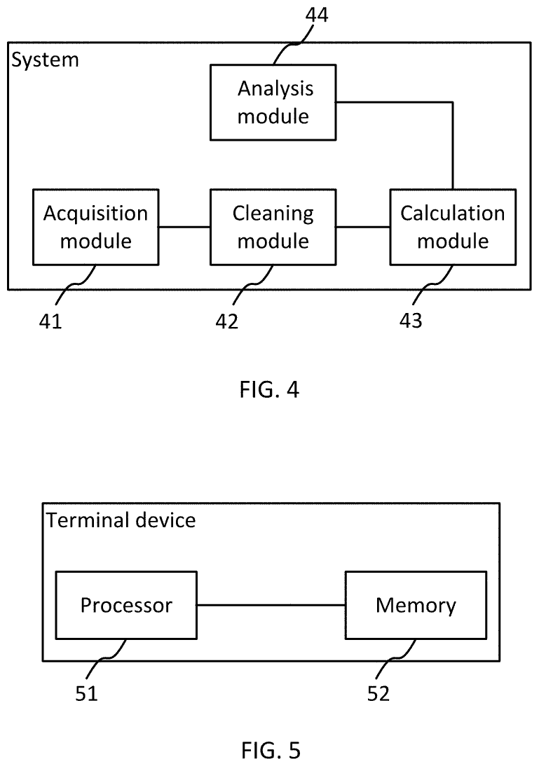

Referring to FIG. 4 now, one embodiment of the voltage-based battery pack state analysis system of the invention is shown, which includes an acquisition module 41, a cleaning module 42, a calculation module 43 and an analysis module 44.

The acquisition module 41 is configured to acquire the cell voltages of each cell and the total voltages of the battery pack within the preset time. For example, the acquisition module 41 in one embodiment may include one or more voltage meters for measuring these voltages.

The cleaning module 42 is coupled with the acquisition module 41 and configured for data cleaning of the acquired cell voltage and the acquired total voltage. For example, the cleaning module 42 in one embodiment may include one or more processors for performing the data cleaning.

The calculation module 43 is coupled with the cleaning module 42 and configured to calculate the voltage standard score of the cell based on the cell voltage after data cleaning, and calculate the voltage standard score of the battery pack based on the total voltage after data cleaning. For example, the calculation module 43 in one embodiment may include one or more processors for performing the calculations.

The analysis module 44 is coupled with the calculation module 43 and configured to perform a time-domain analysis on the voltage standard score of the battery cell and/or the voltage standard score of the battery pack. For example, the analysis module 44 in one embodiment may include a microcontroller unit (MCU) or one or more processors for performing the time-domain analysis.

The detailed structures and principles of the acquisition module 41, the cleaning module 42, the calculation module 43 and the analysis module 44 correspond to the steps in the above disclosed voltage-based battery pack state analysis method, so they are not repeated here.

It should be noted that each of the acquisition module 41, the cleaning module 42, the calculation module 43 and the analysis module 44 of the system/apparatus is disclosed only in accordance with to its logical functions, and may be fully or partially integrated into one physical entity or physically separated during actual implementation. Moreover, these modules can be implemented in the form of calling software through processing elements, or can be implemented in the form of hardware, or some modules can be implemented in the form of calling software through processing elements, and some modules can be implemented in the form of hardware. For example, the x module can be a separate processing element, and can also be integrated in a chip of the above-disclosed system/apparatus. In addition, the x module can also be stored in the memory of the above-disclosed system/apparatus in the form of program codes, and can be invoked by certain processing elements of the above-disclosed system/apparatus to execute the functions of the x module. The implementation of other modules is similar. All or part of these modules can be integrated together, and can also be implemented independently. The processing elements mentioned here may be an integrated circuit with signal processing capability. In the implementation process, each step of the above disclosed method or each module above can be completed by an integrated logic circuit of hardware in the processor element or an instruction in the form of software. The above modules may be one or more integrated circuits configured to implement the above method, for example: one or more application specific integrated circuit (ASIC), one or more microprocessors (e.g., digital signal processor, DSP), one or more field programmable gate array (FPGA), etc. When one of the above modules is implemented in the form of a processing element scheduling program codes, the processing element may be a general-purpose processor, such as a central processing unit (CPU) or other processors that can call program codes. These modules can be integrated together and realized in the form of System-on-a-chip (SOC).

In one embodiment, the computer programs are stored on the storage medium, and when the program is executed by the processor, the above voltage-based battery pack state analysis method is realized. In one embodiment, the storage medium includes various media capable of storing program codes such as ROM, RAM, magnetic disk, U disk, memory card, or optical disk.

As shown in FIG. 5, in one embodiment, the voltage-based battery pack state analysis terminal device of the invention includes at least one processor 51 and a memory 52.

The memory 52 is used to store the computer programs. The memory 52 includes various media capable of storing program codes such as ROM, RAM, magnetic disk, U disk, memory card or optical disk.

The processor 51 is coupled with the memory 52 for executing the computer programs stored in the memory, so that the voltage-based battery pack state analysis terminal device executes the voltage-based battery pack state analysis method described above.

In certain embodiments, the processor can be a general-purpose processor, including a central processing unit (CPU), or a network processor (NP), etc. It can also be a digital signal processor (DSP), application specific integrated circuit (ASIC), field programmable gate array (FPGA), or other programmable logic devices, discrete gate or transistor logic devices, discrete hardware components.

Briefly, the voltage-based battery pack state analysis method, system and terminal of the invention can determine the internal state of the battery pack through the voltage data of the battery pack, which is convenient for practical use and has a high accuracy rate. By fitting the linear variation trend, the internal changes of the battery pack can be visually checked. By increasing the thresholds, the life of the battery pack and single battery cells can be predicted. Further, it may issue timely alerts for some batteries that have gone bad and are getting worsen, thereby effectively improving the safety of the battery. Therefore, the invention effectively overcomes the shortcomings in the prior art and has high industrial application value.

### Example 2

In this exemplary EXAMPLE 2, a method, a system and a terminal device are developed to analyze internal states of a battery pack under different working conditions in real-time, which are on cell parameters such as voltages and currents of the cells, and with no need of professional equipment and disassembling the battery pack.

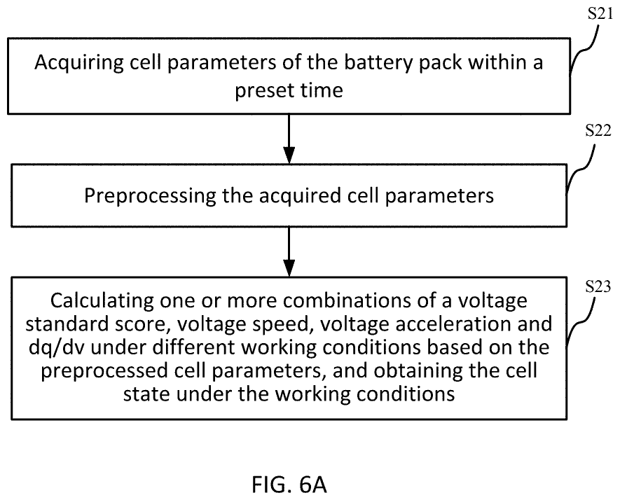

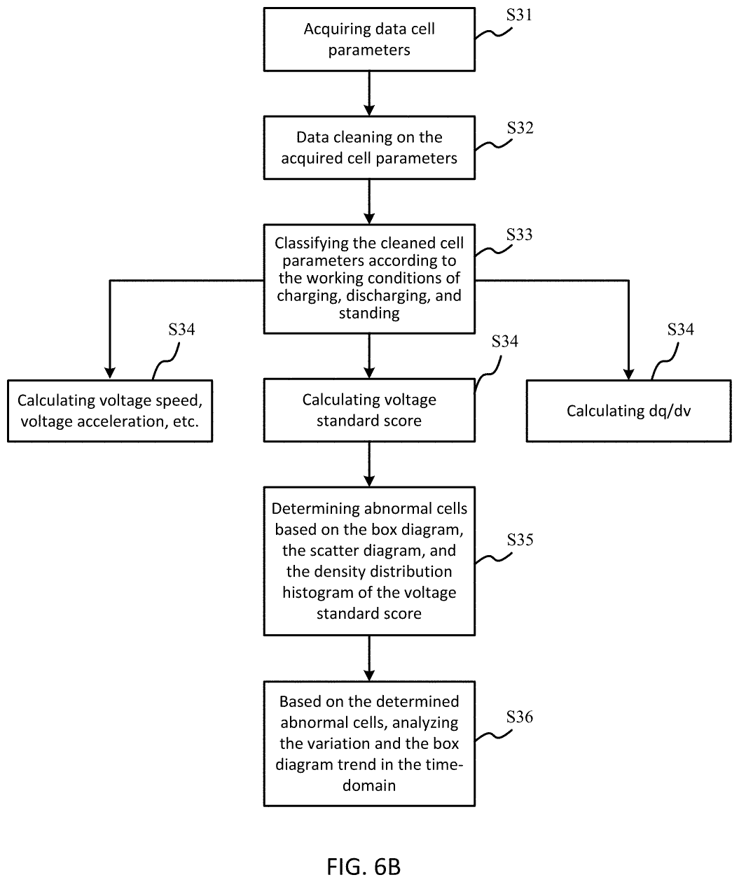

As shown in FIG. 6, in one embodiment, the voltage and current based battery state analysis method comprises the following steps.

At step S21, cell parameters of the battery pack are acquired within a preset time. The cell parameters in one embodiment include the voltage value and current value of each cell.

Specifically, within the preset time, relevant parameters of each single battery cell in the battery pack are acquired. The relevant parameters include the voltage value, V, and current value, I, of each battery cell.

At step S22, the acquired cell parameters is preprocessed.

In order to ensure the reliability of subsequent data analysis, it is necessary to preprocess the acquired cell parameters.

In one embodiment, said preprocessing the cell parameters includes cleaning the cell parameters to remove the abnormal data from the cell parameters, and classifying the cleaned cell parameters according to the working conditions of charging, discharging, and standing:

Specifically, the cell parameters are cleaned through a data cleaning algorithm to remove the abnormal data contained therein. Among them, the data cleaning is the process of re-examining and verifying data, with the purpose of deleting duplicate information, correcting existing errors, and providing data consistency.

Then, the cleaned cell parameters are classified according to the three different working conditions of charging, discharging and standing of the battery, so as to facilitate data analysis for different working conditions. If the cleaned cell parameters are not classified according to the working conditions, the final results may be averaged, and abnormal results cannot be clearly seen.

At step S23, one or more combinations of a voltage standard score, a voltage speed, a voltage acceleration and dq/dv are calculated under different working conditions based on the preprocessed cell parameters, so as to obtain the cell state under the different working conditions. The dq/dv is a first derivative of the amount of electricity (q) with respect to the voltage (V) of each cell. It should be noted that the amount of electricity q can be calculated by the ampere-hour integral method.

Specifically, one or more of the following data can be calculated and analyzed based on the preprocessed cell parameters to know the real-time state of the cells and provide a basis for replacing the battery pack and increasing the capacity of the battery pack.

Calculation and Analysis of Voltage Standard Score:

Specifically, calculating the voltage standard score under different working conditions based on the preprocessed cell parameters, and obtaining the cell state include the following steps:

(1) For a certain working condition, calculating a mean or median value μ_{c} and a standard deviation σ_{c} of the preprocessed voltage values.

(2) Calculating a voltage standard score

$${S}_{i} = \frac{{V}_{i} - {μ}_{c}}{{σ}_{c}}$$

of each cell, where Vᵢ represents the voltage value of the i-th cell in the battery pack. Preferably, after the voltage standard score is calculated, the distribution of the voltage standard score can be checked by drawing a box diagram and a histogram.

(3) Calculating the median or average value of the voltage standard scores within the preset time.

(4) When |the median or average value of the voltage standard score|<a first threshold value, it is determined that the cell is in a healthy state; when the first threshold value ≤|the median or average value of the voltage standard score|<a second threshold value, it is determined that inconsistency occurs in the cell; when the second threshold value ≤|the median or average value of the voltage standard score|<a third threshold value, it is determined that the inconsistency of the battery pack begins getting worsen; and when the third threshold value ≤|the median or average value of the voltage standard score|, it is determined that it is necessary to intervene in the inconsistency of the cell.

Ideally, the voltage standard score of all cells in the battery pack should be 0. However, due to differences in manufacturing processes and operating conditions, the voltage standard score of each cell may be different from each other in actual situations, so the inconsistency of the battery cell can be screened by the above rules. The first threshold value, the second threshold value and the third threshold value may be determined according to actual application scenarios.

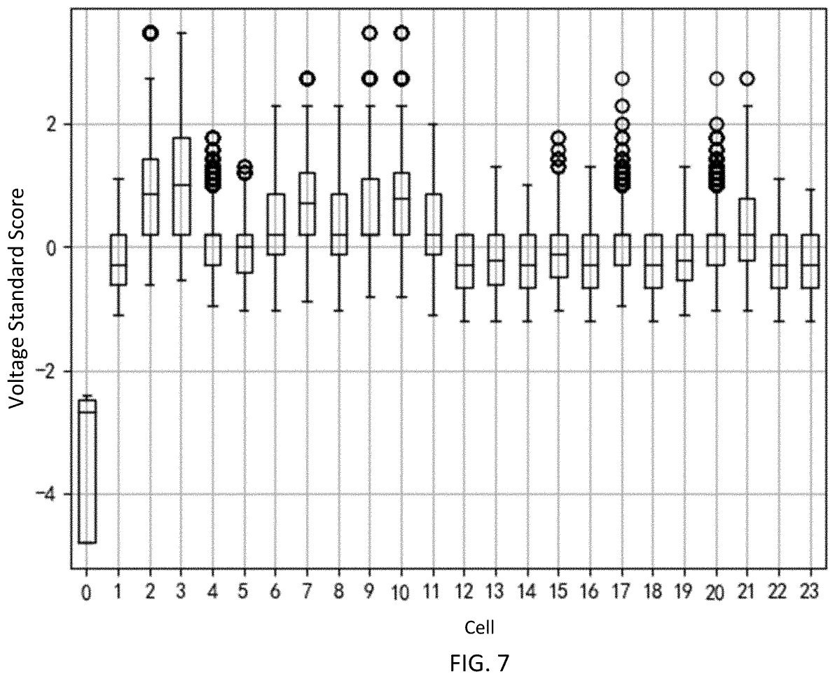

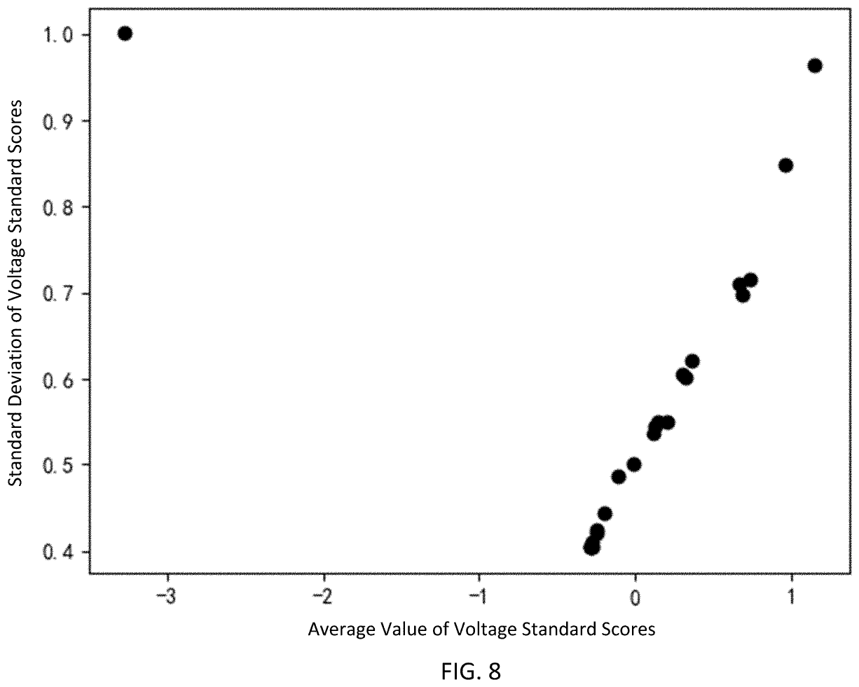

In one embodiment, after obtaining the voltage standard score, the distribution of the voltage standard score of the battery cells can be checked by drawing a box diagram shown in FIG. 7. It can also be checked by calculating the mean value and standard deviation of the voltage standard score, and then drawing a scatter diagram shown in FIG. 8 based on the mean value and the standard deviation. The scatter point distribution in the scatter diagram can be in turn used to prove the calculation result of the voltage standard score, and analyze the dispersion of the voltage standard score. In one embodiment, the scatter diagram uses the mean value and standard deviation as x, y coordinates to plot points, which can reveal the relationship between the values plotted on the grid, and can also show the trend of the data. The scatter diagram are especially useful when there are a large number of data points. Usually, the points of the scatter diagram are mainly divided into the following situations: (1) no obvious relationship, the scatter points are chaotically distributed; (2) linear correlation, the scatter points are roughly distributed on a straight line; (3) relatively concentrated, the scattered points on the scatter diagram are relatively concentrated in a certain area, and only few discrete points are distributed outside the area. It is highly possible that the discrete points are abnormal points.

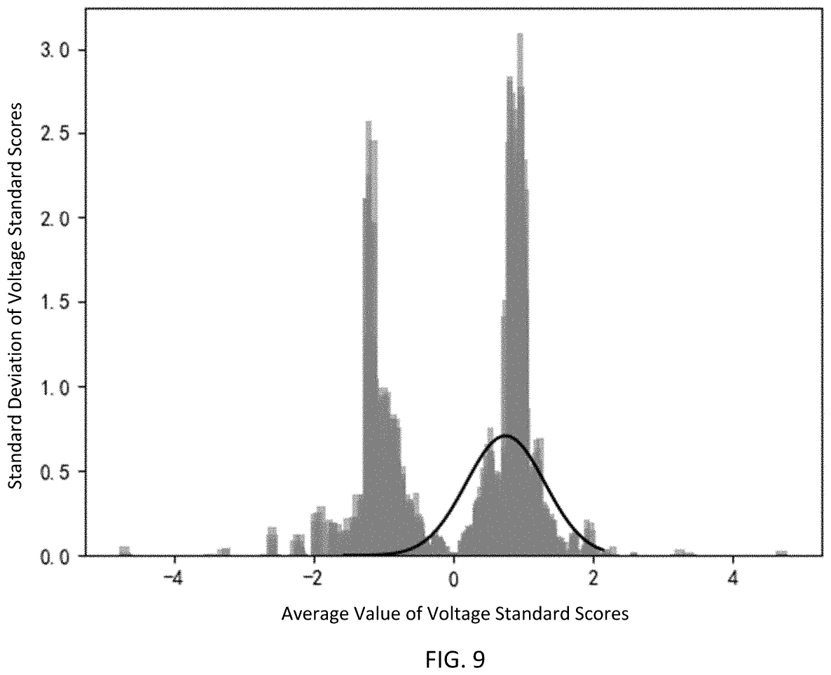

In another embodiment, after obtaining the voltage standard score, the mean value and standard deviation of the voltage standard score are calculated, and the density distribution histogram of the voltage standard score shown in FIG. 9 is drawn based on the mean value and the standard deviation. The distribution of the voltage standard score on the density distribution histogram should obey the normal distribution in the random process. When there is a non-normal distribution, especially when there are two or more peaks on the distribution, it means that there is a serious problem with the consistency of the battery. Usually, the distance S between the peaks can be used as a criterion for judging the cell. For example, when S<threshold 1, it indicates that the cell begins to have inconsistency, which needs to be paid attention to; when the threshold 1≤S<threshold 2, it indicates that the cell is inconsistency; when the threshold 2≤S<threshold 3, it indicates the cell inconsistency begins to worsen; when S≥threshold 3, there is a need to intervene in cell consistency, wherein threshold 1, threshold 2 and threshold 3 are determined according to actual application scenarios.

Calculation and Analysis of the Voltage Speed:

Specifically, calculating the voltage speed under different working conditions based on the preprocessed cell parameters, and obtaining the cell state includes the following steps:

(1) For a certain working condition, calculating the voltage velocity, dv/dt, that is, the first derivative of the voltage with respect to time.

(2) Based on the voltage speed, determining the internal resistance consistency of the cell and whether a micro-short circuit occurs.

Specifically, the voltage velocity dv/dt can represent the variation of voltage. Therefore, this voltage velocity parameter can be used to determine whether there is a micro-short circuit inside the cell. For example, during the charging process, under the premise of excluding the measurement error of the voltage, if the voltage drops, the result of the derivation is negative, which can be used to determine whether there is a short circuit inside the cell, wherein a slow voltage drop means a micro-short circuit, and a sudden voltage drop means a short circuit. Meanwhile, this parameter can be used to qualitatively determine whether there is an internal resistance inconsistency inside the battery pack. If the voltage variation trend of the cells is consistent, it indicates that the internal resistance is basically the same. If the voltage variation trend of the cells is inconsistent, it indicates that the internal resistance is inconsistent.

Analysis and Calculation of the Voltage Acceleration

Specifically, calculating the voltage acceleration under different working conditions based on the preprocessed cell parameters, and obtaining the cell state includes the following steps:

(1) For a certain working condition, calculating the voltage acceleration

$$\frac{d ( dv / dt )}{d t} ,$$

that is, on the basis of the voltage speed, further calculating the first-order derivative of the voltage speed with respect to time.

(2) Based on the voltage acceleration, determining the internal resistance consistency of the cell and whether a micro-short circuit occurs.

Specifically,

$$\frac{d ( dv / dt )}{d t}$$

can be used to further determine the trend of the voltage variation. Therefore, the voltage acceleration parameter can be used to determine the micro-short circuit phenomenon inside the cells and qualitatively determine whether there is an internal resistance inconsistency inside the battery pack. Compared with the voltage speed, the voltage acceleration can optimize the smooth section of the voltage change, that is, the time period when the result of the first derivative of the voltage is 0, and the result is more obvious only by looking at the changing interval. For example, in the continuous charging process, if there is a voltage drop, the first-order derivative of the voltage is negative, and the second-order derivative of the voltage is positive. Therefore, by determining the value of the voltage acceleration during the charging process, the relevant content of the voltage speed can also be determined.

Calculation and Analysis of dq/dv

Specifically, calculating dq/dv under different working conditions based on the preprocessed cell parameters, and obtaining the cell state includes the following steps:

(1) For a certain working condition, calculating the amount of electricity, q, based on the current value, I, of the cell. In one embodiment, the amount of electricity within a certain time t can be calculated based on the current value I, as q=I×t.

(2) Calculating the dq/dv based on the amount of electricity and the voltage. Specifically, based on the amount of electricity at multiple moments, dq/dv=(qₘ−qₘ₋₁)/(vₘ−vₘ₋₁), wherein qₘ and qₘ₋₁ are the amount of electricity at m-th moment and (m−1)-th moment, respectively, while vₘ and vₘ₋₁ are the voltage at m−th moment and (m−1)-th moment, respectively, of the cell.

(3) Based on the dq/dv, determining the consistency of the capacity of the cell and whether the capacity decay occurs. Specifically, the battery capacity can be calculated according to the dq/dv, the consistency of the capacity can be determined by the battery capacity, and the attenuation of the capacity can be determined by referring to the rated capacity.

FIG. 6B shows the voltage and current based battery state analysis method according to another embodiment of the invention. Similarly, the method in the exemplary embodiment includes acquiring data cell parameters at step S31; data cleaning on the acquired cell parameters at step S32; classifying the cleaned cell parameters according to the working conditions of charging, discharging, and standing at step S33; calculating voltage standard score, voltage speed, voltage acceleration, dq/dv, etc. at step S34; determining abnormal cells based on the box diagram, the scatter diagram, and the density distribution histogram of the voltage standard score at step S35; and based on the determined abnormal cells, analyzing the variation and the box diagram trend in the time-domain at step S36.

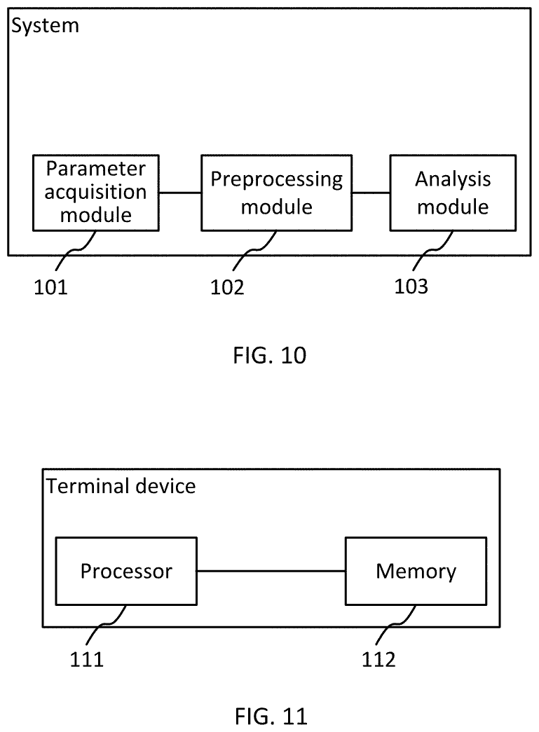

FIG. 10 shows one embodiment of the system for analysis of battery state based on voltage and current parameters. The system includes a parameter acquisition module 101, a preprocessing module 102 and an analysis module 103.

The parameter acquisition module 101 is used to acquire the cell parameters of the battery pack within a preset time; the cell parameters include the voltage value and current value of each cell. For example, the parameter acquisition module 101 in one embodiment may include one or more multi-function meter for measuring various cell parameters such as voltages and currents.

The preprocessing module 102 is coupled with the parameter acquisition module 101 for preprocessing the cell parameters. For example, the preprocessing module 102 in one embodiment may include one or more processors for preprocessing the data.

The analysis module 103 is coupled with the preprocessing module 102, and is used to calculate one or more of the voltage standard score, voltage speed, voltage acceleration and dq/dv under different working conditions based on the preprocessed cell parameters, and obtain the cell state under the working conditions. For example, the analysis module 103 in one embodiment may include a MCU or one or more processors for performing the calculations.

The detailed structures and principles of the parameter acquisition module 101, the preprocessing module 102 and the analysis module 103 correspond to the steps in the voltage and current based battery state analysis method disclosed above, and are not repeated here.

It should be noted that each of the parameter acquisition module 101, the preprocessing module 102 and the analysis module 103 of the system/apparatus is disclosed only in accordance with to its logical functions, and may be fully or partially integrated into one physical entity or physically separated during actual implementation. Moreover, these modules can be implemented in the form of calling software through processing elements, or can be implemented in the form of hardware, or some modules can be implemented in the form of calling software through processing elements, and some modules can be implemented in the form of hardware. For example, the x module can be a separate processing element, and can also be integrated in a chip of the above-disclosed system/apparatus. In addition, the x module can also be stored in the memory of the above-disclosed system/apparatus in the form of program codes, and can be invoked by certain processing elements of the above-disclosed system/apparatus to execute the functions of the x module. The implementation of other modules is similar. All or part of these modules can be integrated together, and can also be implemented independently. The processing elements mentioned here may be an integrated circuit with signal processing capability. In the implementation process, each step of the above disclosed method or each module above can be completed by an integrated logic circuit of hardware in the processor element or an instruction in the form of software. The above modules may be one or more integrated circuits configured to implement the above method, for example: one or more application specific integrated circuit (ASIC), one or more microprocessors (e.g., digital signal processor, DSP), one or more field programmable gate array (FPGA), etc. When one of the above modules is implemented in the form of a processing element scheduling program codes, the processing element may be a general-purpose processor, such as a central processing unit (CPU) or other processors that can call program codes. These modules can be integrated together and realized in the form of System-on-a-chip (SOC).

In one embodiment, the computer programs are stored on the storage medium, and when the program is executed by the processor, the above voltage-based battery pack state analysis method is realized. In one embodiment, the storage medium includes various media capable of storing program codes such as ROM, RAM, magnetic disk, U disk, memory card, or optical disk.

FIG. 11 shows one embodiment of a terminal device for battery state analysis based on voltage and current parameters. The terminal includes a processor 111 and a memory 112.

The memory 112 is used to store computer programs. The memory 112 may include: ROM, RAM, magnetic disk, U disk, memory card or optical disk and other media that can store program codes.

The processor 111 is connected to the memory 112 and is used to execute the computer program stored in the memory, so that the terminal executes the above disclosed voltage and current based battery state analysis method.

In certain embodiments, the processor can be a general-purpose processor, including a central processing unit (CPU), or a network processor (NP), etc. It can also be a digital signal processor (DSP), application specific integrated circuit (ASIC), field programmable gate array (FPGA), or other programmable logic devices, discrete gate or transistor logic devices, discrete hardware components.

Briefly, the method, system and terminal for battery state analysis based on voltage and current can analyze and determine the state of the battery pack under different working conditions in real time. According to the invention, cells with inconsistent and poor performance in the battery pack can be quickly identified and determined, which provide a basis for replacing the battery pack and increasing the capacity of the battery pack. It can accurately determine the micro-short circuit phenomenon of the battery and ensure the safe and stable operation of the battery pack. Therefore, the invention effectively overcomes various shortcomings in the prior art and has high industrial application value.

The foregoing description of the exemplary embodiments of the invention has been presented only for the purposes of illustration and description and is not intended to be exhaustive or to limit the invention to the precise forms disclosed. Many modifications and variations are possible in light of the above teaching. The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the invention pertains without departing from its spirit and scope. Accordingly, the scope of the invention is defined by the appended claims rather than the foregoing description and the exemplary embodiments described therein.

What is claimed is:

1. A method for analyzing a state of a battery pack based on voltages thereof, comprising:
acquiring cell voltages of each cell and total voltages of the battery pack within a preset time;
performing data cleaning on the cell voltages and the total voltages of the battery pack;
calculating a voltage standard score of each cell based on the cell voltages after data cleaning, and calculating a voltage standard score of the battery pack based on the total voltages after data cleaning; and
performing a time-domain analysis on the voltage standard score of each cell and/or the voltage standard score of the battery pack.

2. The method according to claim 1, wherein said calculating the voltage standard score of the battery cell based on the cell voltages after data cleaning comprises:
calculating the mean or median value μ_{c} and the standard deviation σ_{c} of the cell voltages after data cleaning within the preset time; and
calculating the voltage standard score
$${S}_{i} = \frac{{V}_{i} - {μ}_{c}}{{σ}_{c}}$$
of each cell, where Vᵢ represents the voltage value of the i-th cell in the battery pack.

3. The method according to claim 1, wherein said performing the time-domain analysis on the voltage standard score of the battery cell comprises:
dividing the preset time into time intervals of equal length; and
obtaining a variation trend of the voltage standard score of the battery cell based on the time intervals.

4. The method according to claim 3, further comprising:
constructing a scatter diagram based on the voltage standard score of each cell at time intervals; and
constructing a linear variation trend diagram of the voltage standard score based on the scatter diagram.

5. The method according to claim 1, wherein said performing time-domain analysis on the voltage standard score of the battery pack comprises:
dividing the preset time into time intervals of equal length; and
obtaining a variation trend of the voltage standard score of the battery pack based on the time intervals.

6. The method according to claim 5, further comprising:
constructing a scatter diagram based on the voltage standard score of the battery pack at time intervals; and
constructing a linear variation trend diagram of the voltage standard score based on the scatter diagram.

7. A system for analyzing a state of a battery pack based on voltages thereof, comprising:
an acquisition module, a cleaning module, a calculation module, and an analysis module;
wherein the acquisition module is configured to acquire cell voltages of each cell and total voltages of a battery pack within a preset time;
wherein the cleaning module is coupled with the acquisition module and configured to clean data of the acquired cell voltage and the acquired total voltage;
wherein the calculation module is coupled with the cleaning module and configured to calculate the voltage standard score of the cell based on the cell voltages after data cleaning, and calculate the voltage standard score of the battery pack based on the total voltages after data cleaning; and
wherein the analysis module is coupled with the calculation module and configured to perform a time-domain analysis on the voltage standard score of the battery cell and/or the voltage standard score of the battery pack.

8. A terminal device for analyzing a state of a battery pack based on voltages thereof, comprising:
a processor and a memory;
wherein said memory is used to store computer programs; and
wherein the processor is configured to execute the computer programs stored in the memory, so that the terminal device executes the method according to claim 1.

9. A method for analyzing a state of a battery pack based on cell parameters thereof, comprising:
acquiring cell parameters of the battery pack within a preset time, wherein the cell parameters include voltage value and current value of each cell;
preprocessing the acquired cell parameters; and
calculating one or more combinations of a voltage standard score, voltage speed, voltage acceleration and dq/dv under different working conditions based on the preprocessed cell parameters, and obtaining the cell state under the working conditions.

10. The method according to claim 9, wherein said preprocessing the cell parameters comprises:
cleaning abnormal data in the acquired cell parameters; and
classifying the cleaned cell parameters according to the working conditions of charging, discharging, and standing.

11. The method according to claim 9, wherein said calculating the voltage standard score under different working conditions based on the preprocessed cell parameters, and obtaining the cell state comprises:
for a certain working condition, calculating a mean or median value μ_{c} and a standard deviation σ_{c} of the preprocessed voltage values.
calculating a voltage standard score
$${S}_{i} = \frac{{V}_{i} - {μ}_{c}}{{σ}_{c}}$$
of each cell, wherein Vᵢ represents the voltage value of the i-th cell in the battery pack;
calculating a median or average value of the voltage standard score within the preset time, wherein
when |the median or average value of the voltage standard score|<a first threshold value, it is determined that the cell is in a healthy state;
when the first threshold value ≤|the median or average value of the voltage standard score|<a second threshold value, it is determined that inconsistency occurs in the cell;
when the second threshold value ≤|the median or average value of the voltage standard score|<a third threshold value, it is determined that the inconsistency of the battery pack begins getting worsen; and
when the third threshold value ≤|the median or average value of the voltage standard score|, it is determined that it is necessary to intervene in the inconsistency of the cell.

12. The method according to claim 11, further comprising calculating an average value and a standard deviation of the voltage standard score, and drawing a scatter diagram based on the average value and the standard deviation.

13. The method according to claim 9, wherein said calculating the voltage speed under different working conditions based on the preprocessed cell parameters, and obtaining the cell state comprises:
for a certain working condition, calculating the voltage velocity, dv/dt, that is, the first derivative of the voltage with respect to time; and
based on the voltage speed, determining the internal resistance consistency of the cell and whether a micro-short circuit occurs.

14. The method according to claim 9, wherein said calculating the voltage acceleration under different working conditions based on the preprocessed cell parameters, and obtaining the battery state comprises:
for a certain working condition, calculating the voltage acceleration
$$\frac{d ( dv / dt )}{d t} ;$$
and
based on the voltage acceleration, determining the consistency of internal resistances of each cell and whether a micro-short circuit occurs.

15. The method according to claim 9, wherein said calculating dq/dv under different working conditions based on the preprocessed cell parameters, and obtaining the cell state comprises:
for a certain working condition, calculating an amount of electricity, q, based on the current value, I, of the cell;
calculating dq/dv based on the amount of electricity and the voltage; and
based on the dq/dv, determining the consistency of the capacity of the cell and whether the capacity decay occurs.

16. A system for analyzing a state of a battery pack based on voltages and currents thereof, comprising:
a parameter acquisition module, a preprocessing module and an analysis module;
wherein the parameter acquisition module is configured to acquire the cell parameters of the battery pack within a preset time, wherein the cell parameters include voltage value and current value of each cell;
wherein the preprocessing module is configured to preprocess the acquired cell parameters; and
wherein the analysis module is configured to calculate one or more combinations of a voltage standard score, a voltage speed, a voltage acceleration and dq/dv under different working conditions based on the preprocessed cell parameters, and obtain the cell state under the working conditions.

17. A terminal device for analyzing a state of a battery pack based on voltages and currents thereof, comprising: a processor and a memory;
said memory is used to store computer programs; and
wherein the processor is configured to execute the computer program stored in the memory, so that the terminal device executes the method according to claim 9.
